(19) United States
(12) Patent Application Publication
(10) Pub. No.: US 2010/0053130 A1
(43) Pub. Date: Mar. 4, 2010

(54) Driver Integrated Circuit Chip and Driving Circuit of a Flat Panel Display

(76) Inventor: Sheng-Kai HSU, Hsin-Chu (TW)

Correspondence Address: HDLS Patent & Trademark Services, P.O. BOX 220746, CHANTILLY, VA, 20153-0746, US

(21) Appl. No.: 12/355,135

(22) Filed: Jan. 16, 2009

(30) Foreign Application Priority Data
Aug. 29, 2008 (TW) 097133192

(51) Int. Cl. G06F 3/038; H03B 1/00

(52) U.S. Cl. 345/206; 327/108

(57) ABSTRACT

A driver integrated circuit (IC) chip includes an internal operation circuit, a signal output circuit, an output terminal, at least one first power wire and at least one second power wire. The internal operation circuit provides an internal signal. The signal output circuit is electrically coupled to the internal operation circuit and provides an output signal according to the internal signal. The output terminal is electrically coupled to the signal output circuit so as to transmit the output signal. The first power wire is electrically coupled to the signal output circuit. The second power wire is electrically coupled to the internal operation circuit. The first power wire and the second power wire, which are independent from each other, are used to transmit the same type of signals. The present invention also provides a driving circuit for a flat panel display using a plurality of the above-mentioned driver ICs.

### CROSS-REFERENCE TO RELATED APPLICATIONS

This application is based upon and claims the benefit of priority from the prior Taiwanese Patent Application No. 097133192, filed Aug. 29, 2008, the entire contents of which are incorporated herein by reference.

### BACKGROUND

1. Technical Field

The present invention generally relates to a driver integrated circuit (IC) chip and a driving circuit of a flat panel display using the driver IC chips.

2. Description of the Related Art

Flat panel displays such as a liquid crystal display (LCD) and a plasma display have the advantages of high image quality, small size, light weight and a broad application range, and thus are widely applied on consumer electronic products such as a mobile phone, a notebook computer, a desktop display and a television, and have gradually replaced the traditional cathode ray tube (CRT) displays as the main trend in the display industry.

Driver IC chips for providing same type functions in a conventional driving circuit of a flat panel display, such as source driver IC chips or gate driver IC chips generally are connected in cascade to transmit power signals. Since the driver IC chips each use one power supply path to power internal small current circuits (e.g., a level shifter, and an input stage and a middle stage of an output buffer amplifier) and a large current circuit (e.g., an output stage of an output buffer amplifier), a large supply current is required to provide.

However, the large supply current easily causes a large voltage drop, which would influence normal operations of the internal small current circuits of the driver IC chips, especially the tailed driver IC chip(s) of the cascade connected driver IC chips.

### BRIEF SUMMARY

The present invention relates to a driver IC chip can effectively avoid a part of internal circuits thereof (e.g., small current circuits) to suffer from a large voltage drop which would result in abnormal operation of the driver IC chip.

The present invention further relates to a driving circuit of a flat panel display which can use a relatively low power supply and provide a stable driving signal applied to the flat panel display.

In order to achieve the above-mentioned advantages, a driver IC chip in accordance with an embodiment of the present invention is provided. The driver IC chip includes an internal operation circuit, a signal output circuit, an output terminal, at least one first power wire and at least one second power wire. The internal operation circuit is for generating an internal signal. The signal output circuit is electrically coupled to the internal operation circuit and for providing an output signal according to the internal operation circuit. The output terminal is electrically coupled to the signal output circuit and for transmitting the output signal. The at least one first power wire is electrically coupled to the signal output circuit. The at least one second power wire is electrically coupled to the internal operation circuit. The at least one first power wire and the at least one second power wire are independent from each other and used to transmit same type of signals.

In one embodiment, the signal output circuit includes an output stage of an output buffer amplifier.

In one embodiment, the internal operation circuit includes at least one of a level shifter, a digital-to-analog converter, an input stage and a middle stage of an output buffer amplifier, and a reference voltage generation circuit.

In one embodiment, the same type of signals are analog signals.

In one embodiment, the at least one second power wire includes an analog ground wire, a connection location of the internal operation circuit and the analog ground wire contains a deep second-type well formed between a first-type substrate and a first-type well which is formed on the first-type substrate.

A driving circuit of a flat panel display in accordance with another embodiment of the present invention is provided. The flat panel display includes a display area having a plurality of pixels formed therein, and the driving circuit is formed at the periphery of the display area. The driving circuit includes a plurality of the above-mentioned driver IC chips, a plurality of first transmission lines and a plurality of second transmission lines. The first transmission lines are electrically coupled to the respective first power wires of the driver IC chips. The second transmission lines are electrically coupled to the respective second power wires of the driver IC chips. The first transmission lines and the second transmission lines are independent from each other and used to transmit same type of signals.

In one embodiment, the signal output circuit of each of the driver IC chips of the driving circuit includes an output stage of an output buffer amplifier.

In one embodiment, the internal operation circuit of each of the driver IC chips of the driving circuit includes at least one of a level shifter, a digital-to-analog converter, an input stage and a middle stage of an output buffer amplifier, and a reference voltage generation circuit.

In one embodiment, the same type of signals are analog signals.

In one embodiment, the at least one second power wire of each of the driver IC chips of the driving circuit includes an analog ground wire, a connection location of the internal operation circuit and the analog ground line contains a deep second-type well, the deep second-type well is formed between a first-type substrate and a first-type well which is formed on the first-type substrate.

In one embodiment, the driver IC chips of the driving circuit are connected in cascade through the first transmission lines.

In one embodiment, the driver IC chips of the driving circuit are connected in cascade through the second transmission lines.

In one embodiment, the driver IC chips of the driving circuit are connected in cascade through the first transmission lines and the second transmission lines.

In the above-mentioned embodiments of the present invention, since power supply paths for the internal operation circuit which requires a relatively small current and the signal output circuit which requires a relatively large current are independent from each other, any one of the internal operation circuit and the signal output circuit is not influenced by a voltage drop caused by the other one. Accordingly, the normal operation of the internal operation circuit of the driver IC chip would not be affected. Furthermore, when the driver IC chip is used in the driving circuit of a flat panel display, a normal operation of the driving circuit can be maintained and a relatively low power supply is practicable to supply a stable driving signal applied to the flat panel display.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a schematic circuit block diagram of a driver IC chip in accordance with an embodiment of the present invention.

FIG. 2 is a schematic circuit block diagram of a driver IC chip in accordance with another embodiment of the present invention.

FIG. 3 is a schematic partial view of the driver IC chip of FIG. 1.

FIG. 4 is an exemplary circuit block diagram of the driver IC chip of FIG. 1.

FIG. 5 is a schematic view of a flat panel display using a plurality of the driver IC chips of FIG. 1, in accordance with an embodiment of the present invention.

FIG. 6 is a schematic view of a flat panel display using a plurality of the driver IC chips of FIG. 2, in accordance with an embodiment of the present invention.

FIGS. 7A-7C respectively show the driver IC chips in FIG. 5 electrically connected in cascade by a plurality of first transmission lines, a plurality of second transmission lines, and a plurality of first and second transmission lines.

FIGS. 8A-8C respectively show the driver IC chips in FIG. 6 electrically connected in cascade by a plurality of first transmission lines, a plurality of second transmission lines, and a plurality of first and second transmission lines.

### DETAILED DESCRIPTION

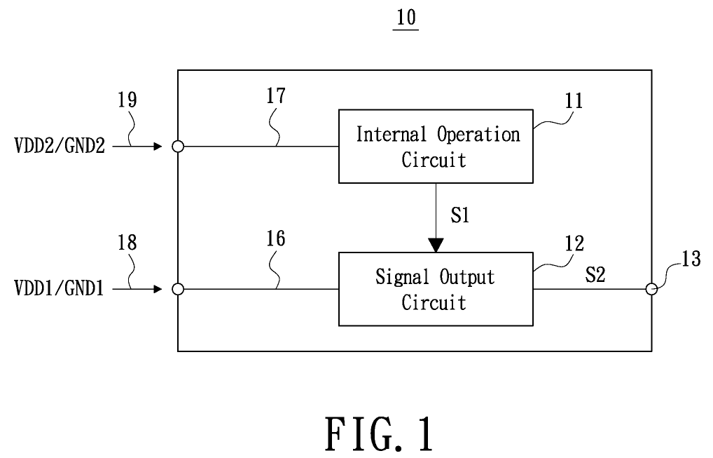

Referring to FIG. 1, a driver IC chip 10 in accordance with an embodiment of the present invention includes an internal operation circuit 11, a signal output circuit 12, an output terminal 13, a first power wire 16 and a second power wire 17. The driver IC chip 10 can be a source driver IC chip or a gate driver IC chip of a flat panel display.

The internal operation circuit 11 is for generating an internal signal S1. The signal output circuit 12 is electrically coupled to the internal operation circuit 11 and for providing an output signal S2 according to the internal signal S1. The output terminal 13 is electrically coupled to the signal output circuit 12 and for transmitting the output signal S2. The internal operation circuit 11 requires a relatively small current, and the signal output circuit 12 requires a relatively large current. The first power wire 16 is electrically coupled to the signal output circuit 12 and for transmitting an external power signal 18 (e.g., a high-potential signal VDD1 or a ground signal GND1) to the signal output circuit 12. The second power wire 17 is electrically coupled to the internal operation circuit 11 and for transmitting another external power signal 19 (e.g., a high-potential signal VDD2 or a ground signal GND2) to the internal operation circuit 11. The first power wire 16 and the second power wire 17 are independent from each other. The external power signals 18, 19 respectively transmitted by the first power wire 16 and the second power wire 17 are the same type of signals (e.g., analog power signals or digital power signals), and the external power signals 18, 19 also are independent from each other.

In other words, the first power wire 16 and the second power wire 17 can simultaneously transmit the respective analog power signals (or digital power signals). Since the first power wire 16 and the second power wire 17 are independent from each other and the external power signals 18, 19 also are independent from each other, any one of the internal operation circuit 11 and the signal output circuit 12 is not influenced by a voltage drop caused by the other one.

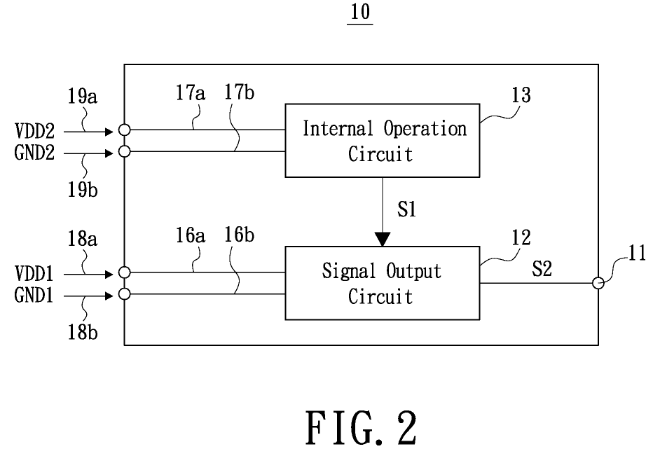

Referring to FIG. 2, a driver IC chip in accordance with another embodiment of the present invention is provided. In this embodiment, two first power wires 16a, 16b are electrically coupled to the signal output circuit 12 and respectively for transmitting external power signals 18a, 18b to the signal output circuit 12. The external power signal 18a can be a high-potential signal VDD1 and the external power signal 18b can be a ground signal GND1. Two second power wires 17a, 17b are electrically coupled to the internal operation circuit 11 and respectively for transmitting external power signals 19a, 19b to the internal operation circuit 11. The external power signal 19a can be a high-potential signal VDD2, and the external power signal 19b can be a ground signal GND2. The first power wires 16a, 16b and the second power wires 17a, 17b are independent from each other. The first power wires 16a, 16b and the second power wires 17a, 17b are for transmitting the same type of signals, e.g., analog power signals AVDD1, AGND1, AVDD2, AGND2, or digital power signals DVDD1, DGND1, DVDD2, DGND2. That is to say, the first power wires 16a, 16b and the second power wires 17a, 17b can simultaneously transmit the respective analog power signals (or digital power signals). Since the first power wires 16a, 16b and the second power wires 17a, 17b are independent from each other and the external power signals 18a, 18b and 19a, 19b respectively transmitted by the first power wires 16a, 16b and the second power wires 17a, 17b also are independent from each other, any one of the internal operation circuit 11 and the signal output circuit 12 is not influenced by a voltage drop caused by the other one.

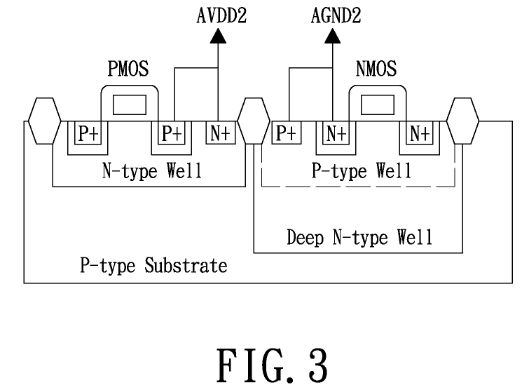

Referring to FIG. 3, a schematic partial view of the driver IC chip 10 is provided. As seen from the FIG. 3, a connection location of the internal operation circuit 11 and the second power wire 17b (i.e., an analog ground wire in this embodiment for transmitting the analog power signal AGND2) contains a deep N-type well. The deep N-type well is formed between a P-type substrate and a P-type well so as to suppress a noise between the P-type substrate and the P-type well of the internal operation circuit 11. According to the needs of practical processes, a connection location between the first power wire 16a and the signal output circuit 12 can be added with a deep N-type well between a P-type substrate and a P-type well of the signal output circuit 12. It is understood that, when the P-type well is changed to be a N-type well, the deep N-type well can be correspondingly replaced by a deep P-type well.

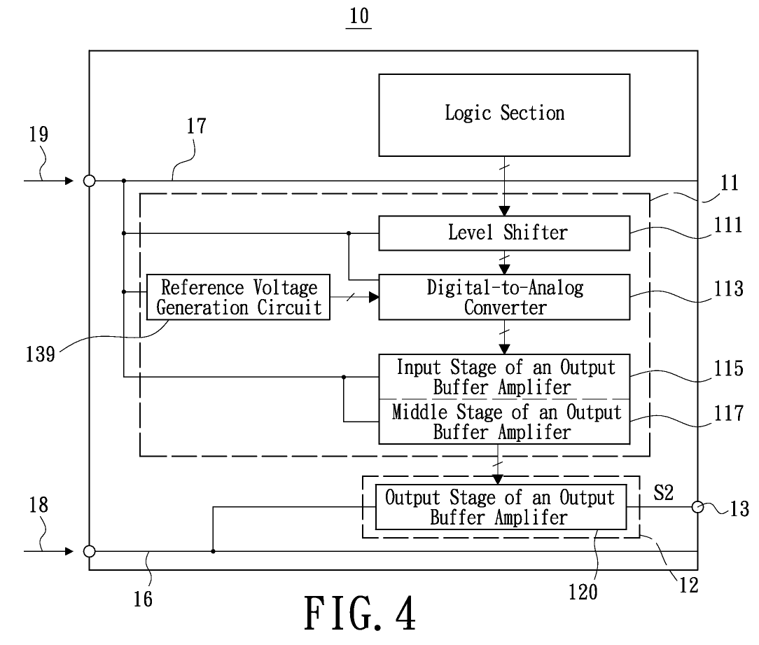

Referring to FIG. 4, an exemplary circuit block diagram of the driver IC chip 10 where the first power wire 16 and the second power wire 17 are for transmitting analog power signals is provided. As shown in FIG. 4, the driver IC chip 10 is a source driver IC chip. The internal operation circuit 11 includes a level shifter 111, a digital-to-analog converter 113, an input stage 115 and a middle stage 117 of an output buffer amplifier, and a reference voltage generation circuit 119. The signal output circuit 12 includes an output stage 120 of an output buffer amplifier. The internal operation circuit 11 of the driver IC chip 10 supplies an output signal S2 via the output stage of the output buffer amplifier 120 to for example a flat panel display, so as to provide driving signals for driving a plurality of pixels of the flat panel display. The output signal S2 is delivered to the flat panel display by the output terminal 13. The external power signal 18 is transmitted to the output stage of the output buffer amplifier 120 by the first power wire 16. Another external power signal 19 is transmitted to the level shifter 111, the digital-to-analog converter 113, the input stage 115 and the middle stage 117 of the output buffer amplifier, and the reference voltage generation circuit 119 by the second power wire 17.

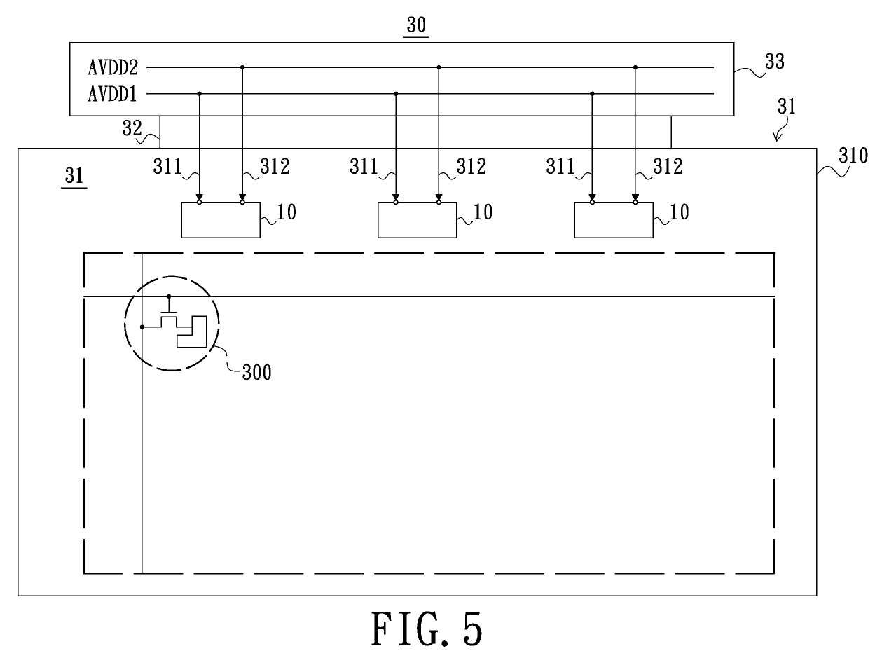

Referring to FIG. 5, a flat panel display 30 using a plurality of the driver IC chips 10 of FIG. 1 in accordance with an embodiment of the present invention is provided. As shown in FIG. 5, the flat panel display 30 includes a display area (as denoted by the dashed rectangle of FIG. 5) having a plurality of pixels 300 formed therein, a driving circuit 31, a flexible printed circuit board 32 and a printed circuit board 33. The driving circuit 31, the flexible printed circuit board 32 and the printed circuit board 33 are formed at the periphery of the display area. The driving circuit 31 is formed on a glass substrate 310. The driving circuit 31 includes a plurality of the driver IC chips 10, a plurality of first transmission lines 311 and a plurality of second transmission lines 312. Each of the first transmission lines 311 is electrically coupled to the first power wire 16 of a corresponding one of the driver IC chips 10 and for transmitting an external power signal (e.g., the analog power signal AVDD1) to the signal output circuit 12 of the corresponding one driver IC chip 10. Each of the second transmission lines 312 is electrically coupled to the second power wire 17 of a corresponding one of the driver IC chips 10 and for transmitting another external power signal (e.g., the analog power signal AVDD2) to the internal operation circuit 11 of the corresponding one driver IC chip 10. The first transmission lines 311 and the second transmission lines 312 are independent from each other. The first transmission lines 311 and the second transmission lines 312 preferably are formed in a process of manufacturing thin film transistors in the display area and directly formed on the glass substrate 310. The driver IC chips 10 can be a plurality of source driver IC chips or a plurality of gate driver IC chips for providing same type functions.

The printed circuit board 33 generally has a DC-to-DC converter for providing analog power signals AVDD1 and AVDD2. The analog power signals AVDD1 and AVDD2 respectively are transmitted to the first transmission lines 311 and the second transmission lines 312 through the flexible printed circuit board 32.

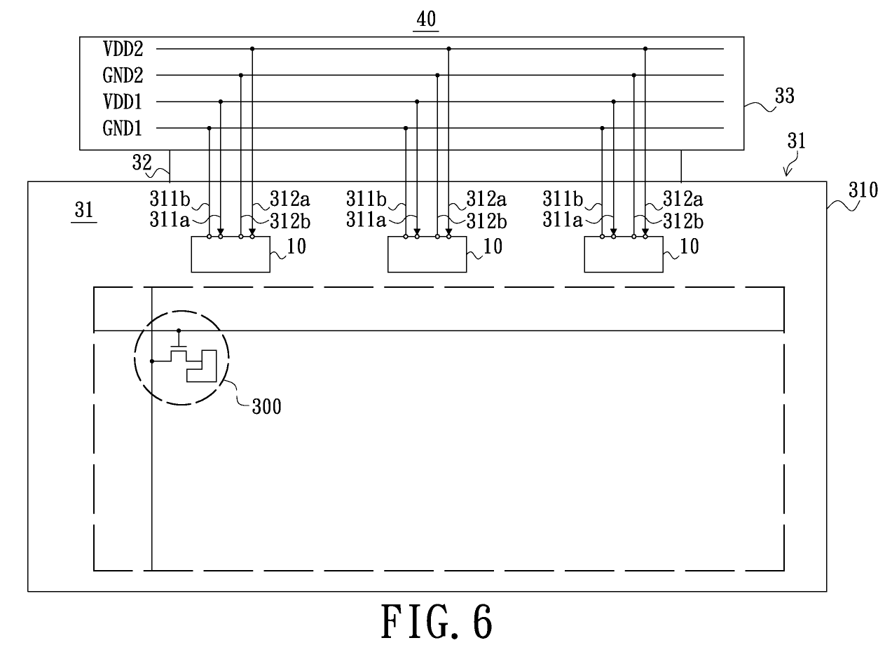

Referring to FIG. 6, a flat panel display 40 using a plurality of the driver IC chips 10 of FIG. 2 in accordance with another embodiment of the present invention is provided. In this embodiment, two first power wires 16a, 16b (as shown in FIG. 2) are electrically coupled to the signal output circuit 12 of each of the driver IC chips 10 and respectively for transmitting the power signal VDD1 from the first transmission line 311a and the power signal GND1 from the second transmission line 311b to the signal output circuit 12.

Likewise, two second power wires 17a, 17b (as shown in FIG. 2) are electrically coupled to the internal operation circuit 11 of each of the driver IC chips 10 and respectively for transmitting the power signal VDD2 from the second transmission line 312a and the power signal GND2 from the second transmission line 312b to the internal operation circuit 11.

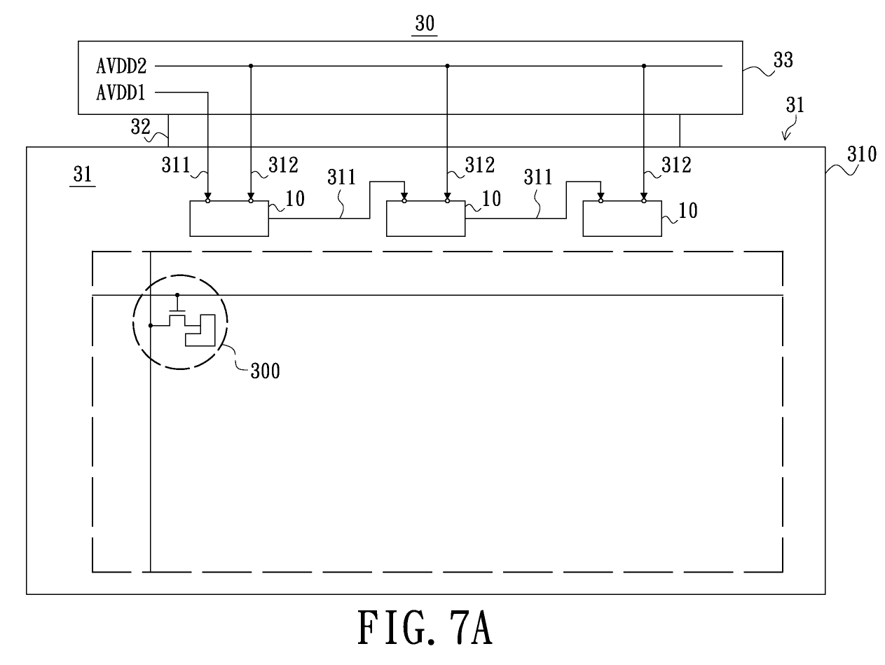

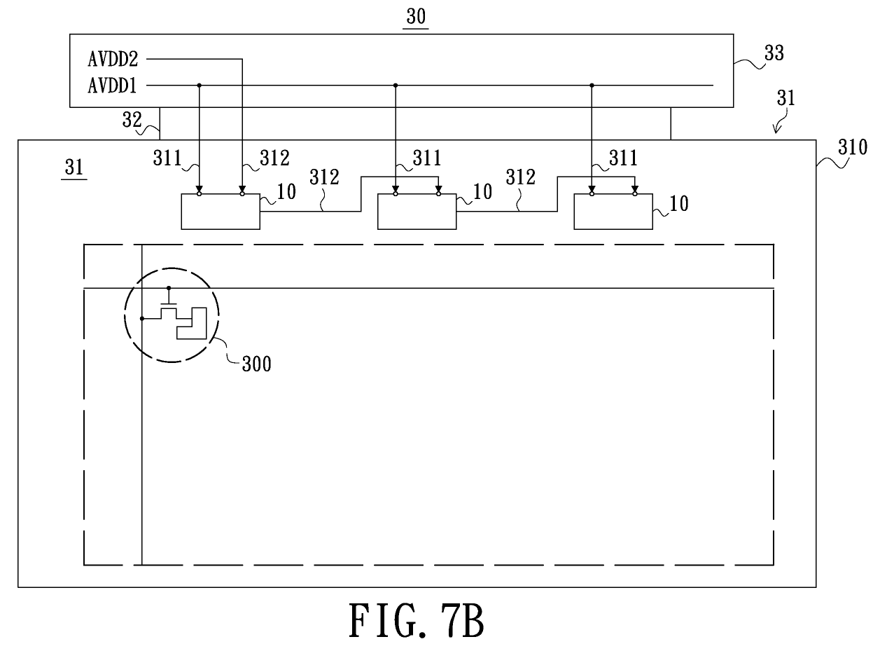

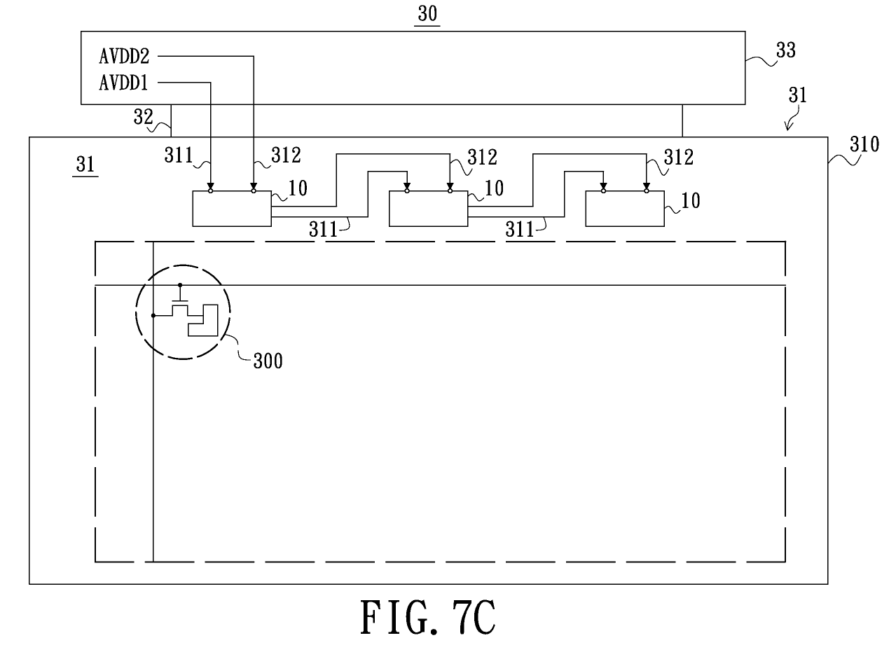

Referring to FIGS. 7A-7C, preferably, the first transmission lines 311 and the first power wires 16 of the driver IC chips 10 are electrically connected in cascade as shown in FIG. 7A in accordance with an embodiment. The second transmission lines 312 and the second power wires 17 of the driver IC chips 10 are electrically connected in cascade as shown in FIG. 7B in accordance with another embodiment. In other embodiment, the first transmission lines 311 and the first power wires 16 of the driver IC chips 10 can be electrically connected in cascade and the second transmission lines 312 and the second power wires 17 of the driver IC chips 10 can be electrically connected in cascade as shown in FIG. 7C.

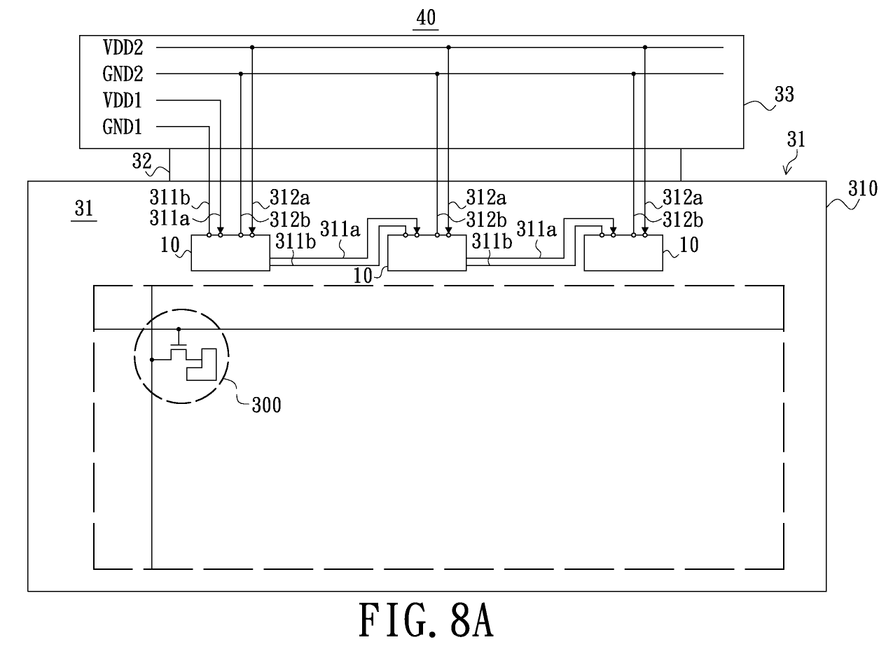

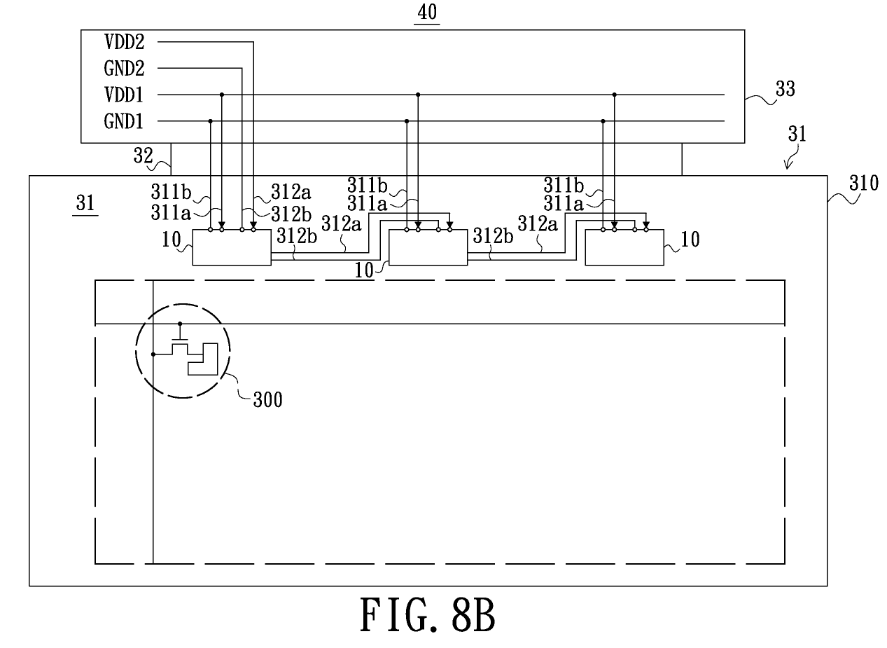

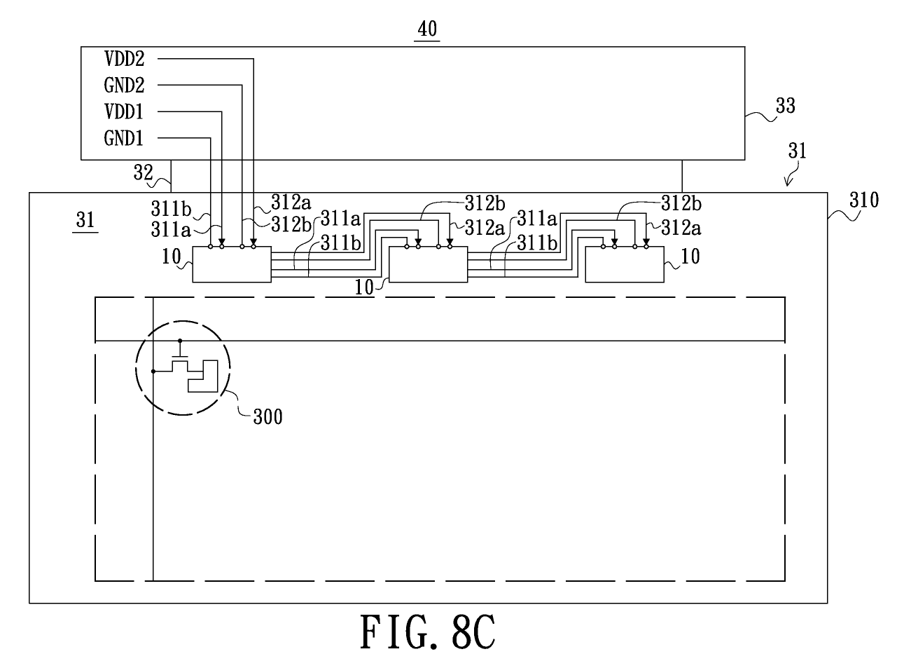

Referring to FIGS. 8A-8C, preferably, the first transmission lines 311a, 311b and the first power wires 16a, 16b of the driver IC chips 10 are electrically connected in cascade as shown in FIG. 8A in accordance with an embodiment. The second transmission lines 312a, 312b and the second power wires 17a, 17b of the driver IC chips 10 are electrically connected in cascade as shown in FIG. 8B in accordance with another embodiment. In other embodiment, the first transmission lines 311a, 311b and the first power wires 16a, 16b of the driver IC chips 10 can be electrically connected in cascade and the second transmission lines 312a, 312b and the second power wires 17a, 17b of the driver IC chips 10 can be electrically connected in cascade as shown in FIG. 8C.

In summary, in the above-mentioned embodiments of the present invention, since power supply paths for the internal operation circuit which requires a relatively small current and the signal output circuit which requires a relatively large current are independent from each other, any one of the internal operation circuit and the signal output circuit is not influenced by a voltage drop caused by the other one. Accordingly, the normal operation of the internal operation circuit of the driver IC chip would not be affected. Furthermore, when the driver IC chip is used in the driving circuit of a flat panel display, a normal operation of the driving circuit can be maintained and a relatively low power supply is practicable to supply a stable driving signal applied to the flat panel display.

In addition, the driver IC chips in accordance with the above-mentioned embodiments of the present invention are not limited to source driver IC chips and gate driver IC chips, and can be other driver IC chips each of which has a need of independent power supply paths respectively for a small current circuit and a large current circuit. Furthermore, the circuit structural configuration of the driver IC chip in accordance with the embodiments of the present invention is not limited to the circuit structural configuration illustrated in FIG. 4, and can be determined according to the requirements of practical application.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A driver integrated circuit chip comprising:
an internal operation circuit for generating an internal signal;
a signal output circuit electrically coupled to the internal operation circuit and for providing an output signal according to the internal signal;
an output terminal electrically coupled to the signal output circuit and for transmitting the output signal;
at least one first power wire electrically coupled to the signal output circuit; and
at least one second power wire electrically coupled to the internal operation circuit;
wherein the at least one first power wire and the at least one second power wire are independent from each other and for transmitting same type of signals.

2. The driver integrated circuit chip as claimed in claim 1, wherein the signal output circuit comprises an output stage of an output buffer amplifier.

3. The driver integrated circuit chip as claimed in claim 1, wherein the internal operation circuit comprises at least one of a level shifter, a digital-to-analog converter, an input stage and a middle stage of an output buffer amplifier, and a reference voltage generation circuit.

4. The driver integrated circuit chip as claimed in claim 1, wherein the same type of signals are analog signals.

5. The driver integrated circuit chip as claimed in claim 4, wherein the at least one second power wire comprises an analog ground wire, a connection location of the internal operation circuit and the analog ground wire contains a deep second-type well, the deep second-type well is formed between a first-type substrate and a first-type well which is formed on the first-type substrate.

6. A driving circuit of a flat panel display, the flat panel display comprising a display area having a plurality of pixels formed therein, the driving circuit being formed at the periphery of the display area and comprising:
a plurality of driver integrated circuit chips each of which comprising:
an internal operation circuit for generating an internal signal;
a signal output circuit electrically coupled to the internal operation circuit and for providing an output signal according to the internal signal;
an output terminal electrically coupled to the signal output circuit and for transmitting the output signal to drive the pixels;
at least one first power wire electrically coupled to the signal output circuit; and
at least one second power wire electrically coupled to the internal operation circuit;
a plurality of first transmission lines electrically coupled to the respective first power wires of the driver integrated circuit chips; and
a plurality of second transmission lines electrically coupled to the respective second power wires of the driver integrated circuit chips;
wherein the first transmission lines and the second transmission lines are independent from each other and for transmitting same type of signals.

7. The driving circuit of the flat panel display as claimed in claim 6, wherein the signal output circuit of each of the driver integrated circuit chips comprises an output stage of an output buffer amplifier.

8. The driving circuit of the flat panel display as claimed in claim 6, wherein the internal operation circuit of each of the driver integrated circuit chips comprises at least one of a level shifter, a digital-to-analog converter, an input stage and a middle stage of an output buffer amplifier, and a reference voltage generation circuit.

9. The driving circuit of the flat panel display as claimed in claim 6, wherein the same type of signals are analog signals.

10. The driving circuit of the flat panel display as claimed in claim 6, wherein the at least one second power wire of each of the driver integrated circuit chips comprises an analog ground wire, a connection location of the internal operation circuit and the analog ground wire contains a deep second-type well, the deep second-type well is formed between a first-type substrate and a first-type well which is formed on the first-type substrate.

11. The driving circuit of the flat panel display as claimed in claim 6, wherein the driver integrated circuit chips are electrically connected in cascade by the first transmission lines.

12. The driving circuit of the flat panel display as claimed in claim 6, wherein the driver integrated circuit chips are electrically connected in cascade by the second transmission lines.

13. The driving circuit of the flat panel display as claimed in claim 11, wherein the driver integrated circuit chips are electrically connected in cascade by the second transmission lines.
